(19) United States
(12) Patent Application Publication
(10) Pub. No.: US 2023/0422592 A1
(43) Pub. Date: Dec. 28, 2023

(54) MANUFACTURING EQUIPMENT OF LIGHT-EMITTING DEVICE

(71) Applicant: Semiconductor Energy Laboratory Co., Ltd., Atsugi-shi, Kanagawa-ken (JP)

(72) Inventors: Shingo EGUCHI, Atsugi (JP); Hiroki ADACHI, Tochigi (JP); Kenichi OKAZAKI, Atsugi (JP); Naoto KUSUMOTO, Isehara (JP); Kensuke YOSHIZUMI, Atsugi (JP); Shunpei YAMAZAKI, Setagaya (JP)

(21) Appl. No.: 18/037,373

(22) PCT Filed: Nov. 25, 2021
(86) PCT No.: PCT/IB2021/060951

§ 371 Date: May 17, 2023

(30) Foreign Application Priority Data
Dec. 7, 2020 (JP) 2020-202401
Dec. 7, 2020 (JP) 2020-202402

(51) Int. Cl. H10K 71/00; H10K 71/16; H10K 71/20; G03F 7/40; G03F 7/00

(52) U.S. Cl. CPC H10K 71/811; H10K 71/164; H10K 71/233; G03F 7/40; G03F 7/0002

(57) ABSTRACT

Manufacturing equipment of a light-emitting device with which steps from formation to sealing of a light-emitting element can be successively performed is provided. The manufacturing equipment includes a vacuum controlled cluster and an atmosphere controlled cluster and has a function of forming the light-emitting device by forming, over a substrate provided with a first electrode, an island-shaped organic compound over the first electrode, a second electrode over the organic compound, and a protective film over the second electrode through a plurality of film formation steps in the vacuum cluster, a lithography step in the atmosphere controlled cluster, and an etching step in the vacuum cluster.

### TECHNICAL FIELD

One embodiment of the present invention relates to manufacturing equipment and a manufacturing method of a light-emitting device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display device, a liquid crystal display device, a light-emitting apparatus, a lighting device, a power storage device, a memory device, an image capturing device, an operation method thereof, and a manufacturing method thereof.

### BACKGROUND ART

In recent years, higher-resolution display panels have been required. Examples of devices that require high-resolution display panels include a smartphone, a tablet terminal, and a notebook computer. Furthermore, higher resolution has been required for a stationary display device such as a television device or a monitor device along with an increase in definition. An example of a device required to have the highest resolution is a device for virtual reality (VR) or augmented reality (AR).

Examples of a display device that can be used for a display panel include, typically, a liquid crystal display device, a light-emitting apparatus including a light-emitting element such as an organic EL (Electro Luminescence) element or a light-emitting diode (LED), and electronic paper performing display by an electrophoretic method or the like.

For example, an organic EL element has a structure where a layer containing a light-emitting organic compound is held between a pair of electrodes. By applying a voltage to this element, light emission can be obtained from the light-emitting organic compound. A display device using such an organic EL element does not need a backlight that is necessary for a liquid crystal display device and the like; thus, a thin, lightweight, high-contrast, and low-power display device can be obtained. Patent Document 1, for example, discloses an example of a display device that includes an organic EL element.

### REFERENCE

### Patent Document

[Patent Document 1] Japanese Published Patent Application No. 2002-324673

### SUMMARY OF THE INVENTION

### Problems to be Solved by the Invention

As an organic EL display device capable of full-color display, a structure in which white-light-emitting elements and color filters are combined and a structure in which R, G, and B light-emitting elements are formed in the same plane are known.

The latter structure is ideal in terms of power consumption, and light-emitting materials are separately deposited using a metal mask or the like in manufacture of medium- and small-size panels under the existing circumstances. However, the process using a metal mask has low alignment accuracy and accordingly requires that the area occupied by a light-emitting element in a pixel be reduced and the gap from the light-emitting element that is included in an adjacent pixel be widened.

Therefore, an object of the process using a metal mask is to increase the density of pixels and emission intensity. It is preferable to increase the area of a light-emitting element with the use of a lithography step or the like for increasing the area occupied by the light-emitting element. However, the reliability of a material included in the light-emitting element is lowered when impurities (e.g., water, oxygen, and hydrogen) in the air enter the material, necessitating performing a plurality of steps in a region whose atmosphere is controlled.

In view of this, an object of one embodiment of the present invention is to provide manufacturing equipment of a light-emitting device with which steps from formation to sealing of a light-emitting element can be successively performed without exposure to the air. Another object is to provide manufacturing equipment of a light-emitting device with which a light-emitting element can be formed without using a metal mask. Another object is to provide a method for manufacturing a light-emitting device.

Note that the description of these objects does not preclude the existence of other objects. One embodiment of the present invention does not need to achieve all these objects. Note that other objects will be apparent from the description of the specification, the drawings, the claims, and the like, and other objects can be derived from the description of the specification, the drawings, the claims, and the like.

### Means for Solving the Problems

One embodiment of the present invention relates to manufacturing equipment and a manufacturing method of a light-emitting device.

One embodiment of the present invention is manufacturing equipment of a light-emitting device. The manufacturing equipment includes a load lock chamber, a vacuum controlled cluster, and an atmosphere controlled cluster. The load lock chamber is connected to the vacuum controlled cluster through a first gate valve; the load lock chamber is connected to the atmosphere controlled cluster through a second gate valve; the pressure in the load lock chamber is controlled to be a reduced pressure or the atmosphere therein is controlled to be an inert gas atmosphere; the pressure in the vacuum controlled cluster is controlled to be a reduced pressure; the atmosphere in the atmosphere controlled cluster is controlled to be an inert gas atmosphere; the vacuum controlled cluster includes a first delivery device, a plurality of film formation apparatuses, and an etching apparatus; the atmosphere controlled cluster includes a second delivery device and a plurality of apparatuses performing a lithography step; and the manufacturing equipment forms the light-emitting device by forming, over a substrate provided with a first electrode, an island-shaped organic compound over the first electrode, a second electrode over the organic compound, and a protective film over the second electrode through a plurality of film formation steps in the vacuum controlled cluster, a lithography step in the atmosphere controlled cluster, and an etching step in the vacuum controlled cluster.

It is preferable that each of the plurality of film formation apparatuses be one or more selected from an evaporation apparatus, a sputtering apparatus, a CVD apparatus, and an ALD apparatus, and the etching apparatus be a dry etching apparatus.

The vacuum controlled cluster preferably includes a vacuum baking apparatus. Alternatively, the load lock chamber is preferably connected to a vacuum baking apparatus through a third gate valve.

As the plurality of apparatuses performing the lithography step, an application apparatus, a light-exposure apparatus, a development apparatus, and a baking apparatus can be included. Alternatively, as the plurality of apparatuses performing the lithography step, an application apparatus and a nanoimprint apparatus can be included.

The load lock chamber preferably includes a substrate rotating mechanism rotating the substrate about an axis perpendicular to the center of the top surface of the substrate. The load lock chamber may be connected to either a load/unload chamber or a load chamber and an unload chamber through a fourth gate valve.

In the vacuum controlled cluster, the substrate attached to a substrate delivering jig can be subjected to treatment. The substrate delivering jig can include a first jig and a second jig, and the substrate can be held between the first jig and the second jig.

The first jig can include a flat-plate portion having a rectangular top surface shape, and can include a plurality of through holes penetrating the first jig from a first side surface of the flat-plate portion to a second side surface opposing the first side surface. The through holes can be used to deliver a substrate to which the substrate delivering jig is attached and to reverse the substrate. The second jig can include an opening portion.

The vacuum controlled cluster can include a device detaching the substrate delivering jig.

The vacuum controlled cluster can include a device reversing a substrate to which the substrate delivering jig is attached.

### Effect of the Invention

According to one embodiment of the present invention, manufacturing equipment of a light-emitting device with which steps from formation to sealing of a light-emitting element can be successively performed without exposure to the air can be provided. Alternatively, manufacturing equipment of a light-emitting device with which a light-emitting element can be formed without using a metal mask can be provided. Further alternatively, a method for manufacturing a light-emitting device can be provided.

Note that the description of these effects does not preclude the existence of other effects. One embodiment of the present invention does not need to have all these effects. Effects other than these can be derived from the description of the specification, the drawings, the claims, and the like.

### BRIEF DESCRIPTION OF THE DRAWINGS

FIG. 1 is a diagram illustrating manufacturing equipment.

FIG. 2A and FIG. 2B are diagrams illustrating a substrate delivering jig.

FIG. 3A is a diagram illustrating the sizes of a through hole of a substrate delivering jig and a hand portion of a delivery device. FIG. 3B and FIG. 3C are diagrams each illustrating a substrate delivering jig and a delivery device.

FIG. 4A is a diagram illustrating a substrate reversing device. FIG. 4B to FIG. 4D are diagrams illustrating the substrate reversing device and a substrate delivering jig.

FIG. 5A to FIG. 5C are diagrams illustrating substrate reversing operation.

FIG. 6A to FIG. 6C are diagrams illustrating substrate reversing operation.

FIG. 7A is a diagram illustrating a sputtering apparatus. FIG. 7B is a diagram illustrating a dry etching apparatus.

FIG. 8A to FIG. 8D are diagrams illustrating a display device.

FIG. 9A and FIG. 9B are diagrams each illustrating a display device.

FIG. 10A to FIG. 10D are diagrams illustrating a manufacturing method of a display device.

FIG. 11A to FIG. 11D are diagrams illustrating a manufacturing method of a display device.

FIG. 12A to FIG. 12E are diagrams illustrating a manufacturing method of a display device.

FIG. 13 is a diagram illustrating manufacturing equipment.

### MODE FOR CARRYING OUT THE INVENTION

Embodiments are described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

### Embodiment 1

In this embodiment, manufacturing equipment of a light-emitting device that is one embodiment of the present invention is described with reference to drawings.

One embodiment of the present invention is manufacturing equipment mainly used for formation of a light-emitting element (also referred to as a light-emitting device) such as an organic EL element. It is preferable to use a lithography step in order to downscale the organic EL element or to increase the area occupied by the organic EL element in a pixel. However, the reliability is impaired when impurities such as water, oxygen, and hydrogen enter the organic EL element. Therefore, some ingenuity is necessary; for example, the atmosphere needs to be controlled to have a low dew point from the manufacturing stage.

With the manufacturing equipment of one embodiment of the present invention, a film formation step, a lithography step, an etching step, and a sealing step for forming an organic EL element can be successively performed without exposure to the air. Accordingly, a downscaled organic EL element achieving high luminance and high reliability can be formed.

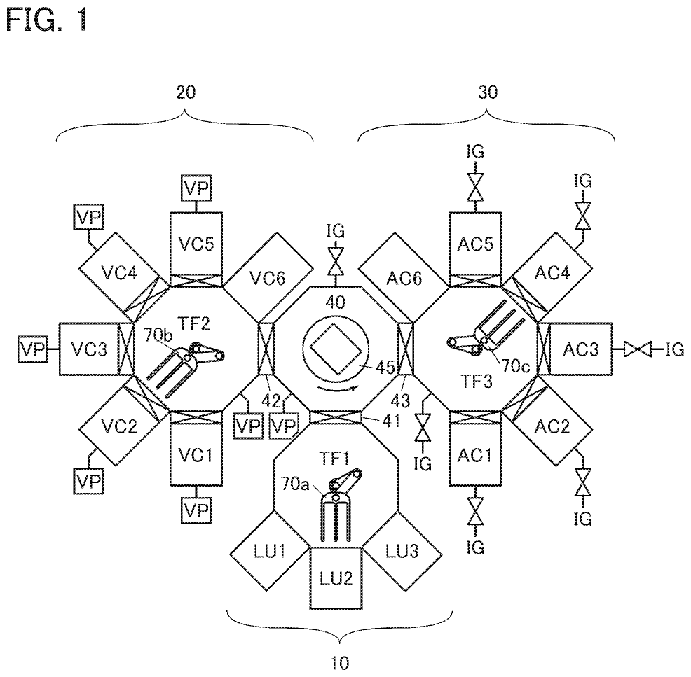

FIG. 1 is a diagram illustrating the manufacturing equipment of a light-emitting device that is one embodiment of the present invention. The manufacturing equipment includes a load/unload unit 10, a vacuum controlled cluster 20, an atmosphere controlled cluster 30, and a load lock chamber 40. In this specification, a group of apparatuses for performing a main process under vacuum (under a reduced pressure) is referred to as a vacuum controlled cluster. A group of apparatuses for performing the main process in a controlled atmosphere is referred to as an atmosphere controlled cluster.

### Load/Unload Unit

The load/unload unit 10 includes load/unload chambers LU (load/unload chambers LU1, LU2, and LU3) and a transfer chamber TF1. The transfer chamber TF1 is connected to the load/unload chambers LU. The transfer chamber TF1 is connected to the load lock chamber 40 through a gate valve 41. The transfer chamber TF1 is provided with a delivery device 70a to be able to deliver a substrate placed in any of the load/unload chambers LU to the load lock chamber 40. The atmosphere in the load/unload chamber LU may be controlled to be an inert gas atmosphere as in the atmosphere controlled cluster 30 described later.

There may be a gate valve between the load/unload chamber LU and the transfer chamber TF1. Although FIG. 1 shows the load/unload chamber LU as an example, a load chamber and an unload chamber may be provided.

### Vacuum Controlled Cluster

The vacuum controlled cluster 20 includes a transfer chamber TF2 and vacuum process apparatuses VC. The number of vacuum process apparatuses VC, which is six (vacuum process apparatuses VC1 to VC6) in the example shown in FIG. 1, may be one or more depending on the purpose. A vacuum pump VP is connected to each vacuum process apparatus VC, and a gate valve is provided between each vacuum process apparatus VC and the transfer chamber TF2. Thus, vacuum processes such as film formation and etching can be performed in parallel in the vacuum process apparatuses VC.

Note that the vacuum process means treatment in an environment where the pressure is controlled to be a reduced pressure. Thus, the vacuum process includes treatment with introduction of a process gas and pressure control, besides treatment under high vacuum.

The transfer chamber TF2 is also provided with an independent vacuum pump VP, so that cross contamination during processes performed in the vacuum process apparatuses VC can be prevented. Like the vacuum process apparatus VC6 shown in FIG. 1, the structure without a gate valve between a vacuum process apparatus and the transfer chamber TF2 may be employed.

The transfer chamber TF2 is connected to the load lock chamber 40 through a gate valve 42. The transfer chamber TF2 is provided with a delivery device 70b to be able to deliver a substrate placed in the load lock chamber 40 to the vacuum process apparatus VC.

As the vacuum process apparatuses VC, film formation apparatuses such as an evaporation apparatus, a sputtering apparatus, a CVD (Chemical Vapor Deposition) apparatus, and an ALD (Atomic Layer Deposition) apparatus can be employed. As the CVD apparatus, a thermal CVD apparatus using heat, a PECVD apparatus (Plasma Enhanced CVD apparatus) using plasma, or the like can be used. As the ALD apparatus, a thermal ALD apparatus using heat, a PEALD apparatus (Plasma Enhanced ALD apparatus) using a plasma-excited reactant, or the like can be used. A dry etching apparatus or the like can be used as an etching apparatus. Alternatively, an auxiliary mechanism, such as a substrate reversing device or a device detaching a substrate delivering jig, may be employed as the vacuum process apparatus VC. Such an auxiliary mechanism can be employed as, for example, the vacuum process apparatus VC6, which has the structure without a gate valve between a vacuum process apparatus and the transfer chamber TF2.

### Atmosphere Controlled Cluster

The atmosphere controlled cluster includes normal-pressure process apparatuses AC that mainly perform steps under normal pressure and a transfer chamber TF3. The number of normal-pressure process apparatuses AC, which is six (normal-pressure process apparatuses AC1 to AC6) in the example shown in FIG. 1, may be one or more depending on the purpose. Note that the step is not necessarily performed under normal pressure, and the pressure may be the negative or positive pressure to some extent compared to normal pressure. In the case where a plurality of the normal-pressure process apparatuses AC are provided, the atmospheric pressures therein may be different from each other.

Valves for introducing an inert gas (IG) are connected to the transfer chamber TF3 and the normal-pressure process apparatuses AC, whereby the atmosphere therein can be controlled to be an inert gas atmosphere. Examples of the inert gas that can be used include nitrogen and a noble gas such as argon or helium. In addition, the inert gas preferably has a low dew point (e.g., −50° C. or lower). When a step is performed in an atmosphere of an inert gas with a low dew point, entry of impurities can be prevented and a highly reliable organic EL element can be formed.

In the example shown in FIG. 1, the normal-pressure process apparatuses AC1 to AC5 are each connected to the transfer chamber TF3 through a gate valve. Providing the gate valve makes it possible to control atmospheric pressure, control the kind of an inert gas, and prevent cross contamination, for example. In the case where there is no need to precisely control these, connection to the transfer chamber TF3 without through a gate valve may be employed as in the normal-pressure process apparatus AC6.

The transfer chamber TF3 is connected to the load lock chamber 40 through a gate valve 43. The transfer chamber TF3 is provided with a delivery device 70c to be able to deliver a substrate placed in the load lock chamber 40 to the normal-pressure process apparatus AC.

As the normal-pressure process apparatuses AC, apparatuses for performing a lithography step can be used. For example, in the case where a photolithography step is performed, a resin (photoresist) application apparatus, a light-exposure apparatus, a development apparatus, a baking apparatus, and the like can be employed. In the case where a nanoimprint lithography step is performed, a resin (e.g., a UV curable resin) application apparatus, a nanoimprint apparatus, and the like can be employed. In addition, depending on the usage, a cleaning apparatus, a wet etching apparatus, an application apparatus, a resist peeling apparatus, and the like may be employed as the normal-pressure process apparatuses AC.

The load lock chamber 40 is provided with a valve for introducing an inert gas and the vacuum pump VP. Thus, the pressure in the load lock chamber 40 can be controlled to be a reduced pressure or the atmosphere therein can be controlled to be an inert gas atmosphere. For example, in the case where a substrate is delivered from the vacuum controlled cluster 20 to the atmosphere controlled cluster 30, operation can be performed in the following manner: the substrate is carried in from the vacuum controlled cluster 20 with the pressure in the load lock chamber 40 reduced, and the substrate is carried out into the atmosphere controlled cluster 30 after the atmosphere in the load lock chamber 40 is set to an inert gas atmosphere.

The load lock chamber 40 is provided with a substrate rotating mechanism 45 by which the substrate delivered is rotated about the Z-axis (the axis perpendicular to the center of the top surface of the substrate). In the case where the substrate has a rectangular top surface shape, rotating the substrate about the Z-axis 90° facilitates carrying in and out the substrate between the transfer chamber TF1 and the transfer chamber TF2 or the transfer chamber TF3. In the case where the substrate has a square or circular top surface shape, the substrate rotating mechanism 45 can be omitted.

With the use of the manufacturing equipment having the above-described structure, the following steps can be performed. First, a substrate is carried in from the load/unload chamber to the vacuum controlled cluster 20 and a film formation step is performed. Then, the substrate is delivered from the vacuum controlled cluster 20 to the atmosphere controlled cluster 30 and a lithography step is performed. Subsequently, the substrate is delivered from the atmosphere controlled cluster 30 to the vacuum controlled cluster 20 and an etching step is performed to form a structure (a light-emitting element such as an organic EL element). Then, a film formation step for forming a protective film covering the structure is performed in the vacuum controlled cluster 20. Subsequently, the substrate is carried out from the vacuum controlled cluster 20 to the load/unload chamber LU.

In the above manner, the structure sealed with the protective film can be carried out into the air without being exposed to the air. That is, in the case where an organic EL element is formed as the structure, entry of an impurity contained in the air can be inhibited and the reliability can be increased.

### Substrate Delivering Jig

In the case where a plurality of steps are performed in the vacuum controlled cluster, the orientation (face-up or face-down orientation) of the substrate placed sometimes differs between the vacuum process apparatuses VC. Thus, the substrate needs to be reversed between steps in some cases.

In a face-up mode, the substrate put on a hand portion of a delivery device can be delivered with the substrate surface over which a structure is formed facing upward. Thus, the substrate can be easily placed on a stage (e.g., an electrode) in the vacuum process apparatus VC. By contrast, in a face-down mode, the substrate needs to be delivered such that the hand portion of the delivery device does not contact the substrate surface. In the case where the substrate is placed in the vacuum process apparatus VC, the substrate should be held by the vicinity of its edge. These problems can be avoided by just holding the substrate by the vicinity of its edge in the case where the substrate is small; however, a large substrate will warp when held by the vicinity of its edge and thus, the large substrate alone is difficult to deliver and place.

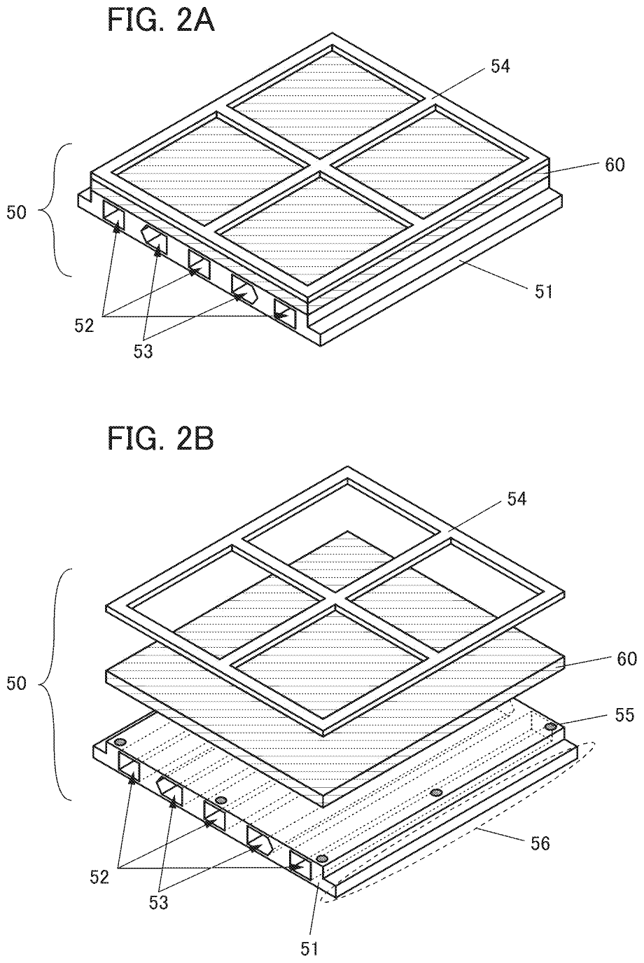

It is thus preferable to use a substrate delivering jig as shown in FIG. 2A and FIG. 2B. The substrate delivering jig includes a jig 51 and a jig 54. FIG. 2A is a diagram of the substrate delivering jig to which a substrate 60 is attached; this structure is referred to as a work substrate 50 in this specification. Holding the substrate 60 between the jig 51 and the jig 54 can inhibit warpage even when the substrate is large, which is effective particularly when the substrate is placed in a face-down mode. The jig 54 includes an opening portion, and the rest is a region necessary for holding the substrate 60. Manufactures such as light-emitting elements are formed in the opening portion; thus, the size and shape of the opening portion are adjusted depending on the purpose.

FIG. 2B is a diagram of the jig 51, the substrate 60, and the jig 54 that are separated in the vertical direction. The jig 51 and the jig 54 are preferably formed using a hard material such as a metal, ceramic, or a cermet. Alternatively, the jig 51 and the jig 54 may be formed of a combination of these materials. FIG. 2B shows an example in which the substrate 60 is held between the jig 51 provided with a magnet 55 and the jig 54 formed using a magnetic metal.

In a different structure, a magnetic metal may be provided in only a portion of the jig 54 that faces the magnet 55 and the rest of the jig 54 may be formed using ceramic or the like. The magnet 55 may be provided on the jig 54 side. Alternatively, the magnet 55 may be provided in both the jig 51 and the jig 54. Note that the substrate 60 may be held between the jig 51 and the jig 54 with the use of a spring or any other structure.

The shape of the jig 51 corresponds to that of the substrate 60; in the case where the substrate 60 has a rectangular top surface shape, it is preferable that the jig 51 also have a rectangular top surface shape and a size larger than or equal to a size close to the size of the substrate 60. In the jig 51 with a rectangular top surface shape, which includes a flat-plate portion, a projection 56 is provided in each of a first end portion that is perpendicular to the top surface of the flat-plate portion and a second end portion that opposes the first end portion, as shown in FIG. 2B. The projection 56 can be used at the time of face-down placement, which will be described later.

A through hole 52 and a through hole 53 are provided between a third end portion that is perpendicular to the first end portion and a fourth end portion that opposes the third end portion.

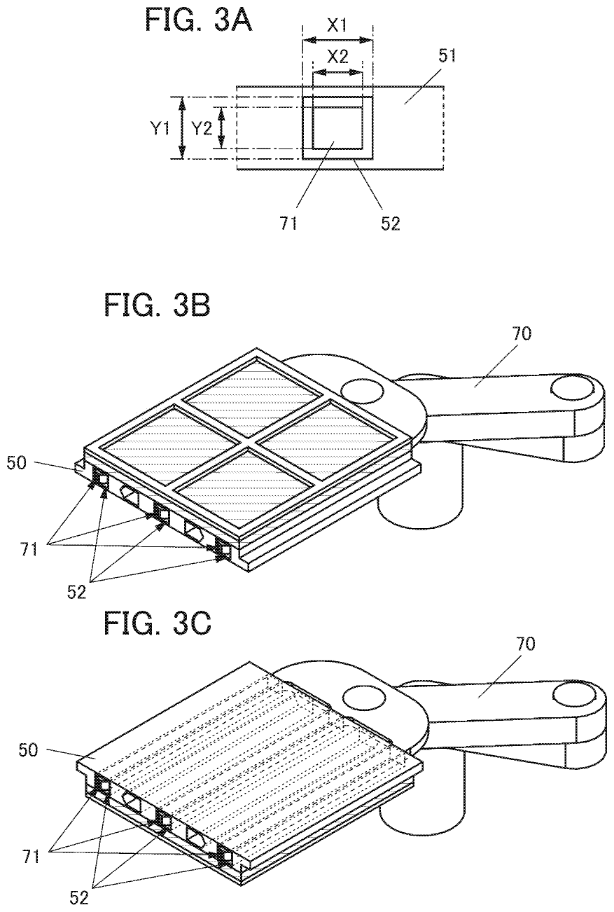

Here, FIG. 3B shows comparison between the size of the through hole 52 and that of a hand portion 71 of the delivery device 70 (any of the delivery devices 70a to 70c). X1>X2 and Y1>Y2 are satisfied when the inner size of a cross section of the through hole 52 perpendicular to the major axis is X1×Y1 and the outer size of a cross section of the hand portion 71 perpendicular to the major axis is X2×Y2. Accordingly, the hand portion 71 of the delivery device 70 can be inserted into the through hole 52 as shown in FIG. 3A.

As shown in FIG. 3C, even the work substrate 50 reversed can be delivered with the hand portions 71 of the delivery device 70 inserted into the through holes 52. Thus, the hand portion 71 does not contact a surface of the substrate 60 or the jig 54, which can prevent damage to and contamination of the surface of the substrate 60, peeling of a film attached to the jig 54, and the like.

The height (Y1) of the inner size of the through hole 52 is larger than the thickness (Y2) of the hand portion 71, whereby the hand portion 71 of the delivery device 70 can be inserted into and removed from the through hole 52 of the work substrate 50 fixed, through only operation of the delivery device 70. This eliminates the need for a pusher pin lifting a substrate or the like in the vacuum process apparatus VC or the like. The number of through holes 52, which is three in FIG. 3B and FIG. 3C, may be two or four or more.

### Substrate Reversing Device

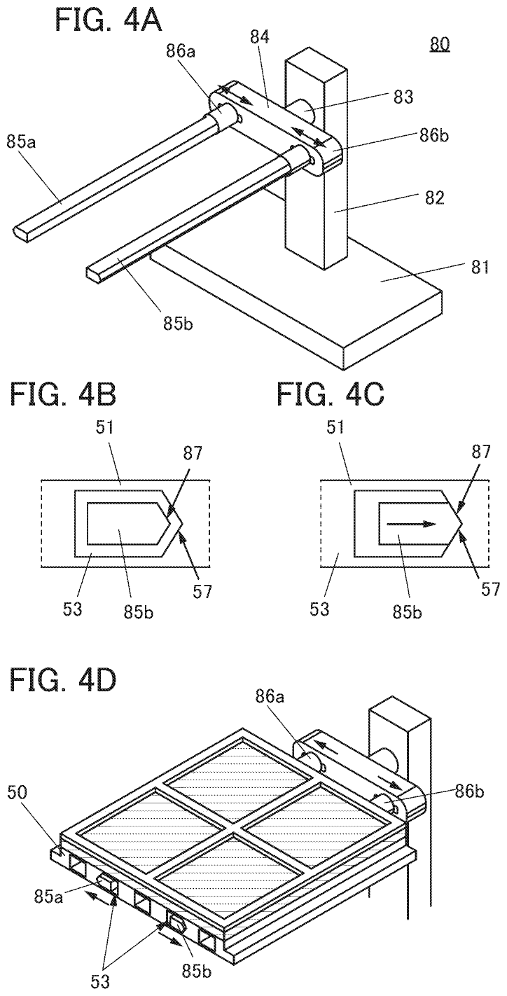

Into the through holes 53, hand portions 85a and 85b of a substrate reversing device 80 shown in FIG. 4A are to be inserted. The substrate reversing device 80 includes a pillar 82 fixed on a support 81, a rotation mechanism 83 fixed on the pillar 82, and a rotation portion 84 fixed on the rotation axis of the rotation mechanism 83. The rotation portion 84 includes horizontal movement mechanisms 86a and 86b. The hand portion 85a is connected to the horizontal movement mechanism 86a, and the hand portion 85b is connected to the horizontal movement mechanism 86b.

FIG. 4B shows a cross section of the hand portion 85b of the substrate reversing device 80 perpendicular to the major axis and a cross section of the through hole 53 perpendicular to the major axis. Part of the cross section of the hand portion 85b perpendicular to the major axis includes a protruding shape portion 87. Part of the cross section of the through hole 53 perpendicular to the major axis includes a depressed shape portion 57.

As shown in FIG. 4C, moving the horizontal movement mechanism 86b such that the protruding shape portion 87 contacts the depressed shape portion 57 brings the protruding shape portion 87 into close contact with the depressed shape portion 57. As shown in FIG. 4D, when the hand portion 85a, which is line-symmetrical to the hand portion 85b, is moved in a similar manner, the hand portions 85a and 85b can be fixed to the work substrate 50. The protruding shape portion 87 and the depressed shape portion 57 may each have a curvature as long as their shapes are such that these portions can be brought into close contact with each other.

In FIG. 4D, the protruding shape portion 87 and the depressed shape portion 57 described above contact each other when the hand portion 85a and the hand portion 85b are moved in such directions that the hand portion 85a and the hand portion 85b are moved away from each other; however, a structure may be employed in which the protruding shape portion 87 and the depressed shape portion 57 described above contact each other when the hand portion 85a and the hand portion 85b are moved in such directions that the hand portion 85a and the hand portion 85b approach each other.

Next, operation for reversing the work substrate 50 is described. Note that the work substrate 50 is assumed to be on standby with the hand portions 71 of the delivery device 70 inserted into the through holes 52 and a surface of the substrate 60 is assumed to face upward.

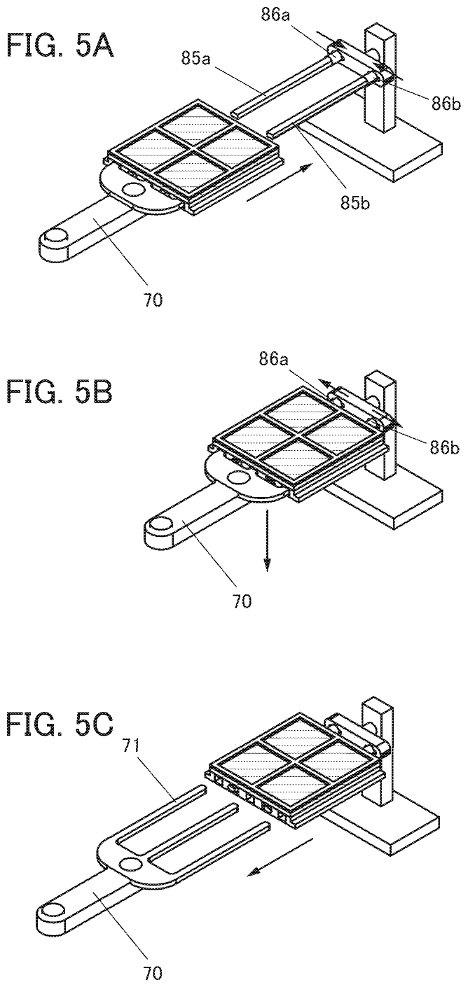

First, the hand portion 85a and the hand portion 85b of the substrate reversing device 80 are moved in such directions that the hand portion 85a and the hand portion 85b approach each other, and the delivery device 70 is operated such that the hand portion 85a and the hand portion are inserted into the through holes 53 (see FIG. 5A).

Subsequently, the hand portion 85a and the hand portion 85b are moved in such directions that the hand portion 85a and the hand portion 85b are moved away from each other, so that the work substrate 50 is fixed to the hand portion 85a and the hand portion 85b. Then, the hand portions 71 of the delivery device 70 are slightly lowered to the height such that the hand portions 71 do not contact the inner walls of the through holes 52 (see FIG. 5B). Then, the hand portions 71 are removed from the through holes 52 (see FIG. 5C).

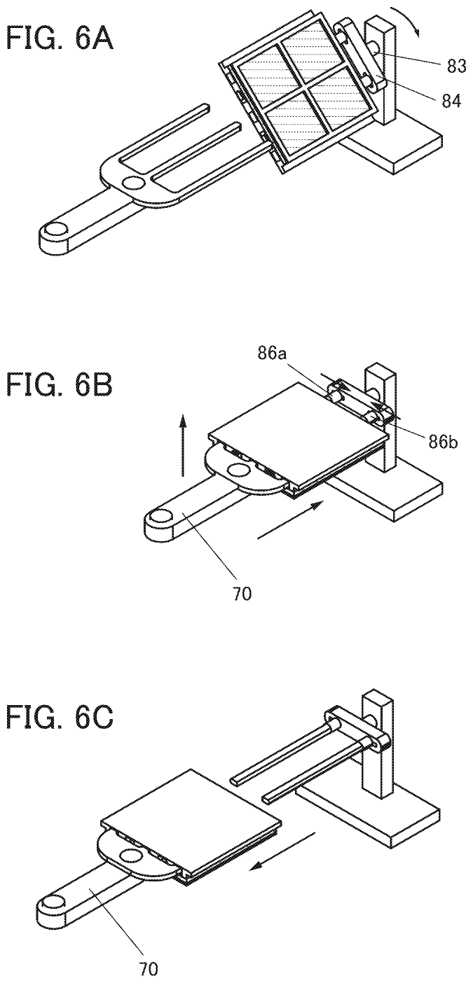

Next, the rotation mechanism 83 rotates the rotation portion 84 (see FIG. 6A), and after a reversal, the hand portions 71 of the delivery device are inserted into the through holes 52. Subsequently, the hand portion 85a and the hand portion 85b of the substrate reversing device 80 are moved in such directions that the hand portion 85a and the hand portion 85b approach each other, so that the hand portion 85a and the hand portion 85b are unfixed from the work substrate 50. Then, the hand portions 71 of the delivery device 70 are slightly raised to the height such that the hand portions 71 contact the inner walls of the through holes 52 (see FIG. 6B).

Then, the hand portions 71 are moved backward, so that the work substrate 50 is removed from the hand portion 85a and the hand portion 85b of the substrate reversing device 80. The operation for reversing the work substrate 50 is as described above. Note that similar operation is performed to return the substrate to the state shown in FIG. 5A from the state shown in FIG. 6C.

### Vacuum Process Apparatus VC

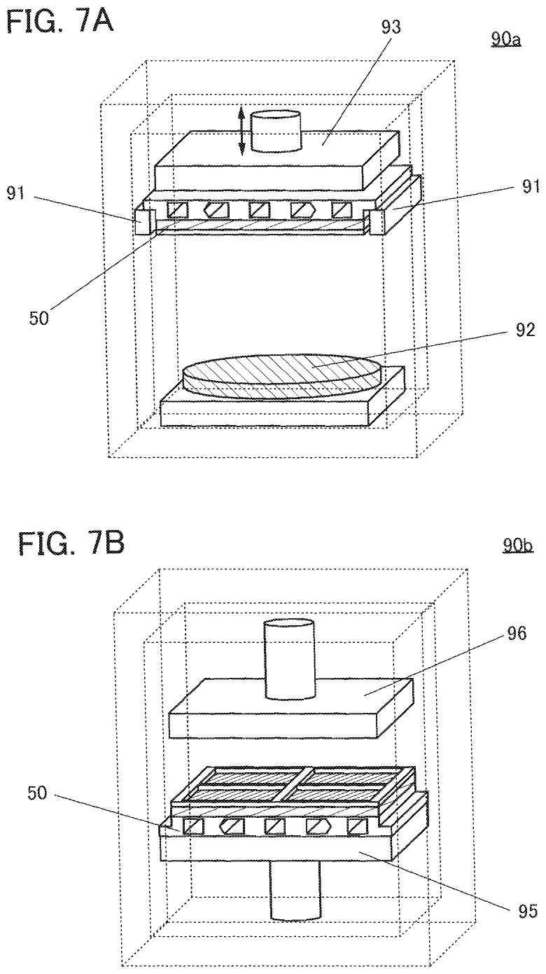

Next, placement of the work substrate 50 in the vacuum process apparatus VC is described. FIG. 7A is a diagram illustrating the vacuum process apparatus VC in which the work substrate 50 is placed in a face-down mode; here, a sputtering apparatus 90a is shown as an example. Note that for clarity, this diagram indicates a chamber with dashed lines and omits a gate valve.

In the sputtering apparatus 90a, there are a pair of rails 91 fixed to the chamber, between a cathode 92 (target) and an anode 93. When the work substrate 50 is placed such that the side surfaces of the projections 56 of the work substrate 50 are put on the rails 91, the work substrate can be placed in a face-down mode in the chamber of the sputtering apparatus 90a.

To facilitate carrying the work substrate 50 into and out of the sputtering apparatus 90a, a vertical mechanism raising and lowering the anode 93 may be provided. The vertical mechanism can make the anode 93 contact the work substrate 50, which makes it possible to efficiently perform application of a bias to the work substrate 50 and/or heating by a heater provided for the anode 93, for example.

An evaporation apparatus in which the work substrate 50 is to be placed in a face-down mode can also employ the structure where the work substrate 50 is to be placed on the rails 91 as in the sputtering apparatus 90a shown in FIG. 7A.

FIG. 7B is a diagram illustrating the vacuum process apparatus VC in which the work substrate 50 is placed in a face-up mode; here, a dry etching apparatus 90b is shown as an example. Note that for clarity, this diagram indicates a chamber with dashed lines and omits a gate valve.

The dry etching apparatus 90b includes a cathode 95 (stage) and an anode 96 that are of a parallel-plate type. When the work substrate 50 is placed such that the jig 51 side thereof contacts the stage, the work substrate 50 can be placed in a face-up mode in the chamber of the dry etching apparatus 90b. Since the work substrate 50 can be carried in and out through only operation of the delivery device 70, a pusher pin lifting the substrate or the like is not needed as already described above.

A CVD apparatus, an ALD apparatus, and the like in which the work substrate 50 is to be placed in a face-up mode can also employ the structure where the work substrate 50 is to be placed on a stage as in the dry etching apparatus 90b shown in FIG. 7B.

With the use of the manufacturing equipment of one embodiment of the present invention described above, a film formation step, a lithography step, an etching step, and a sealing step can be successively performed without exposure to the air. Accordingly, a downscaled organic EL element achieving high luminance and high reliability can be formed.

This embodiment can be implemented in an appropriate combination with the structures described in the other embodiment.

### Embodiment 2

This embodiment describes a specific example for manufacturing a light-emitting element (organic EL element) with the use of manufacturing equipment of a light-emitting device that is one embodiment of the present invention.

In this specification and the like, a device formed using a metal mask or an FMM (fine metal mask) is sometimes referred to as a device having an MM (metal mask) structure. In this specification and the like, a device formed without using a metal mask or an FMM is sometimes referred to as a device having an MML (metal maskless) structure.

In this specification and the like, a structure in which light-emitting layers in light-emitting devices of different colors (here, blue (B), green (G), and red (R)) are separately formed or separately patterned is sometimes referred to as an SBS (Side By Side) structure. In this specification and the like, a light-emitting device capable of emitting white light is sometimes referred to as a white-light-emitting device. Note that a white-light-emitting device that is combined with coloring layers (e.g., color filters) can be a light-emitting device for full-color display.

Structures of light-emitting devices can be classified roughly into a single structure and a tandem structure. A device with a single structure includes one light-emitting unit between a pair of electrodes, and the light-emitting unit preferably includes one or more light-emitting layers. To obtain white light emission, two or more light-emitting layers are selected such that their emission colors are complementary. For example, when emission colors of a first light-emitting layer and a second light-emitting layer are complementary colors, the light-emitting device can be configured to emit white light as a whole. The same applies to a light-emitting device including three or more light-emitting layers.

A device having a tandem structure includes two or more light-emitting units between a pair of electrodes, and each light-emitting unit preferably includes one or more light-emitting layers. To obtain white light emission, the structure is employed in which light from light-emitting layers of a plurality of light-emitting units is combined to enable white light emission. Note that a structure for obtaining white light emission is similar to that in the case of a single structure. In the device with a tandem structure, it is preferable that an intermediate layer such as a charge-generation layer be provided between the plurality of light-emitting units.

When the white-light-emitting device (having a single structure or a tandem structure) and a light-emitting device having an SBS structure are compared to each other, the latter can have lower power consumption than the former. To reduce power consumption, a light-emitting device having an SBS structure is preferably used. Meanwhile, the white-light-emitting device is preferable in terms of lower manufacturing cost or higher manufacturing yield because the manufacturing process of the white-light-emitting device is simpler than that of a light-emitting device having an SBS structure.

The device with a tandem structure may include light-emitting layers emitting light of the same color (e.g., BB, GG, or RR). The tandem structure emitting light from a plurality of layers requires high voltage for light emission but achieves the same emission intensity as a single structure with a smaller current value. Thus, with the tandem structure, current stress on each light-emitting unit can be reduced and the element lifetime can be extended.

### Structure Example

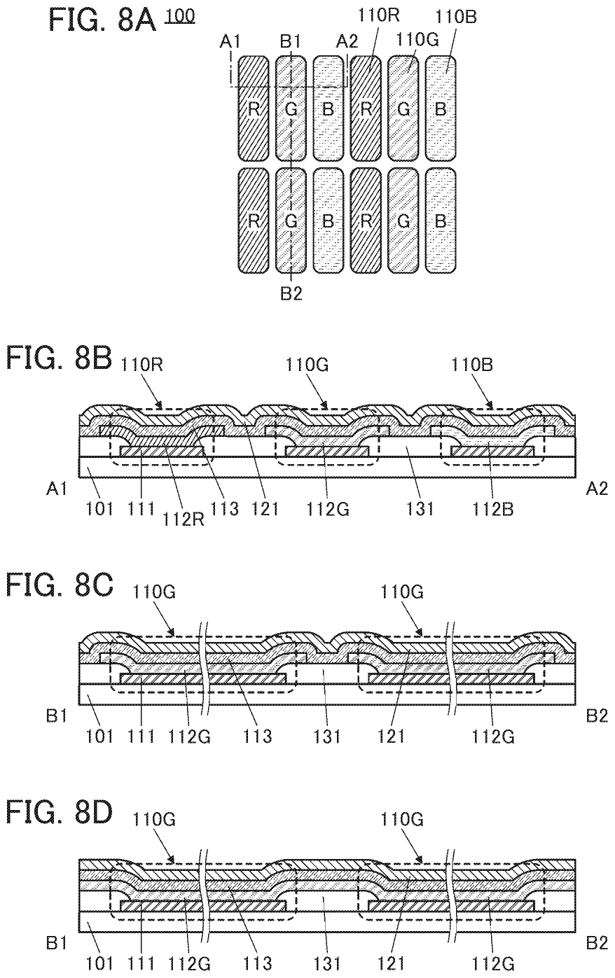

FIG. 8A is a schematic plan view of a display device 100 of one embodiment of the present invention. The display device 100 includes a plurality of light-emitting elements 110R exhibiting red, a plurality of light-emitting elements 110G exhibiting green, and a plurality of light-emitting elements 110B exhibiting blue. In FIG. 8A, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 8A illustrates what is called a stripe arrangement, in which the light-emitting elements of the same color are arranged in one direction. Note that the arrangement method of the light-emitting elements is not limited thereto; another arrangement method such as a delta arrangement, a zigzag arrangement, or a PenTile arrangement may also be used.

As each of the light-emitting elements 110R, the light-emitting elements 110G, and the light-emitting elements 110B, an EL element such as an OLED (Organic Light Emitting Diode) or a QLED (Quantum-dot Light Emitting Diode) is preferably used. As examples of a light-emitting substance contained in the EL element, a substance that emits fluorescent light (a fluorescent material), a substance that emits phosphorescent light (a phosphorescent material), an inorganic compound (e.g., a quantum dot material), a substance that exhibits thermally activated delayed fluorescence (a thermally activated delayed fluorescent (TADF) material), and the like can be given.

FIG. 8B is a schematic cross-sectional view taken along the dashed-dotted line A1-A2 in FIG. 8A, and FIG. 8C is a schematic cross-sectional view taken along the dashed-dotted line B1-B2.

FIG. 8A shows cross sections of the light-emitting element 110R, the light-emitting element 110G, and the light-emitting element 110B. The light-emitting element 110R, the light-emitting element 110G, and the light-emitting element 110B are provided over a substrate 101 and each include a pixel electrode 111 and a common electrode 113.

The light-emitting element 110R includes an EL layer 112R between the pixel electrode 111 and the common electrode 113. The EL layer 112R contains at least a light-emitting organic compound that emits light having a peak in the red wavelength range. An EL layer 112G included in the light-emitting element 110G contains at least a light-emitting organic compound that emits light having a peak in the green wavelength range. An EL layer 112B included in the light-emitting element 110B contains at least a light-emitting organic compound that emits light having a peak in the blue wavelength range.

The EL layer 112R, the EL layer 112G, and the EL layer 112B may each include one or more of an electron-injection layer, an electron-transport layer, a hole-injection layer, and a hole-transport layer in addition to the layer containing a light-emitting organic compound (light-emitting layer).

The pixel electrode 111 is provided in each of the light-emitting elements. The common electrode 113 is provided as one continuous layer shared by the light-emitting elements. A conductive film with a property of transmitting visible light is used for either one of the pixel electrode 111 and the common electrode 113, and a conductive film with a property of reflecting visible light is used for the other. When the pixel electrode 111 has a light-transmitting property and the common electrode 113 has a light-reflecting property, the display device can have a bottom emission structure. Alternatively, the display device can have a top emission structure when the pixel electrode 111 has a light-reflecting property and the common electrode 113 has a light-transmitting property. Note that when both the pixel electrode 111 and the common electrode 113 have a light-transmitting property, the display device can have a dual emission structure. This embodiment describes examples in which a top emission display device and a bottom emission display device are manufactured.

An insulating layer 131 is provided to cover end portions of the pixel electrode 111. End portions of the insulating layer 131 are preferably tapered.

The EL layer 112R, the EL layer 112G, and the EL layer 112B each include a region in contact with the top surface of the pixel electrode 111 and a region in contact with a surface of the insulating layer 131. End portions of the EL layer 112R, the EL layer 112G, and the EL layer 112B are positioned over the insulating layer 131.

As illustrated in FIG. 8B, there is a gap between the EL layers of two light-emitting elements with different colors. In this manner, the EL layer 112R, the EL layer 112G, and the EL layer 112B are preferably provided so as not to be in contact with each other. This suitably prevents unintended light emission from being caused by a current flowing through two adjacent EL layers. As a result, the contrast can be increased, enabling the display device to have high display quality.

FIG. 8C shows an example in which the EL layer 112G is processed into an island shape. As shown in FIG. 8D, the EL layer 112G may be processed into a strip shape to be continuous in the column direction. When the EL layer 112G and the like are formed in a strip shape, a space for dividing the layers is not needed and thus a non-light-emitting region between the light-emitting elements can be reduced, resulting in a higher aperture ratio. FIG. 8C and FIG. 8D each show the cross section of the light-emitting element 110G as an example; the light-emitting element 110R and the light-emitting element 110B can have a similar shape.

A protective layer 121 is provided over the common electrode 113 so as to cover the light-emitting element 110R, the light-emitting element 110G, and the light-emitting element 110B. The protective layer 121 has a function of preventing diffusion of impurities into the light-emitting elements from above.

The protective layer 121 can have, for example, a single-layer structure or a stacked-layer structure including at least an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 121.

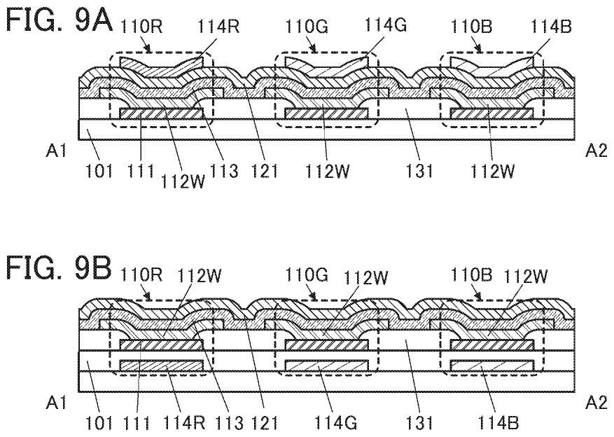

Although FIG. 8A to FIG. 8D show an exemplary structure in which the light-emitting layers of the R, G, and B light-emitting elements are different from each other, one embodiment of the present invention is not limited thereto. For example, as illustrated in FIG. 9A and FIG. 9B, a coloring method may be employed in which the light-emitting elements 110R, 110G, and 110B are formed by providing EL layers 112W that emit white light and providing coloring layers 114R (red), 114G (green), and 114B that overlap with the EL layers 112W. FIG. 9A shows an example of a top emission display device and FIG. 9B shows an example of a bottom emission display device.

The EL layer 112W can have a tandem structure in which EL layers emitting R, G, and B light are connected in series, for example. Alternatively, a structure in which light-emitting layers emitting R, G, and B light are connected in series may be used. As the coloring layers 114R, 114G, and 114B, for example, red, green, and blue color filters can be used.

### Manufacturing Method Example

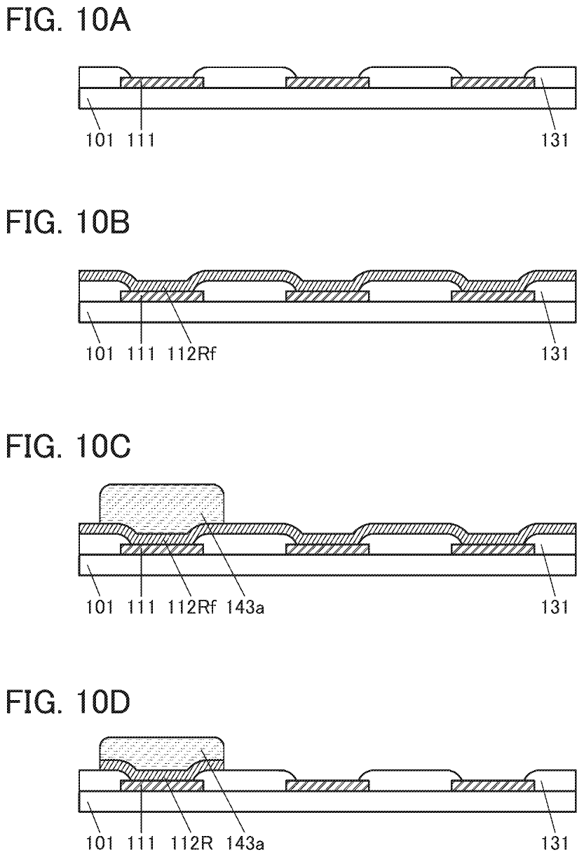

An example of a method for manufacturing a display device of one embodiment of the present invention will be described below with reference to drawings. Description is made here using the display device 100 described in the above structure example as an example. FIG. 10A to FIG. 12E are schematic cross-sectional views of steps in the method for manufacturing the display device described below as an example.

Note that thin films constituting the display device (insulating films, semiconductor films, conductive films, and the like) can be formed by a sputtering method, a chemical vapor deposition (CVD) method, a vacuum evaporation method, an atomic layer deposition (ALD) method, or the like. Examples of the CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given. The manufacturing equipment of one embodiment of the present invention can include an apparatus for forming thin films by the above method.

A method such as spin coating, dipping, spray coating, ink-jetting, dispensing, screen printing, offset printing, a doctor knife method, slit coating, roll coating, curtain coating, or knife coating can be employed for formation of the thin films constituting the display device (insulating films, semiconductor films, conductive films, and the like) and application of a resin used for a lithography step or the like. The manufacturing equipment of one embodiment of the present invention can include an apparatus for forming thin films by the above method. In addition, the manufacturing equipment of one embodiment of the present invention can include an apparatus for applying a resin by the above method.

The thin films constituting the display device can be processed by a photolithography method or the like. Alternatively, the thin films may be processed by a nanoimprinting method. A method in which island-shaped thin films are directly formed by a film formation method using a blocking mask may also be used.

There are two typical methods for processing a thin film using a photolithography method. In one of the methods, a resist mask is formed over a thin film that is to be processed, the thin film is processed by etching or the like, and the resist mask is removed. In the other method, after a photosensitive thin film is formed, exposure and development are performed, so that the thin film is processed into a desired shape.

As the light used for exposure in a photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Exposure may be performed by liquid immersion exposure technique. Furthermore, as the light used for the exposure, extreme ultra-violet (EUV) light or X-rays may be used. Furthermore, instead of the light used for the exposure, an electron beam can also be used. Extreme ultra-violet light, X-rays, or an electron beam is preferably used to enable extremely minute processing. Note that in the case of performing exposure by scanning of a beam such as an electron beam, a photomask is not needed.

For etching of thin films, a dry etching method, a wet etching method, or the like can be used. The manufacturing equipment of one embodiment of the present invention can include an apparatus for processing thin films by the above method.

### Preparation of Substrate 101

As the substrate 101, a substrate having at least heat resistance high enough to withstand later heat treatment can be used. In the case where an insulating substrate is used as the substrate 101, a glass substrate, a quartz substrate, a sapphire substrate, a ceramic substrate, an organic resin substrate, or the like can be used. Alternatively, it is possible to use a semiconductor substrate such as a single crystal semiconductor substrate or a polycrystalline semiconductor substrate formed using silicon, silicon carbide, or the like; a compound semiconductor substrate of silicon germanium or the like; or an SOI substrate.

As the substrate 101, it is particularly preferable to use the semiconductor substrate or the insulating substrate over which a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

### Formation of Pixel Electrode 111

Next, a plurality of the pixel electrodes 111 are formed over the substrate 101. First, a conductive film to be the pixel electrodes 111 is formed, a resist mask is formed by a photolithography method, and an unnecessary portion of the conductive film is removed by etching. After that, the resist mask is removed, so that the pixel electrodes 111 can be formed.

In the case where a top emission display device is manufactured, it is preferable to use, for the pixel electrodes 111, a material (e.g., silver or aluminum) having reflectance as high as possible in the whole wavelength range of visible light. The pixel electrodes 111 formed using the material can be referred to as electrodes having a light-reflecting property. In that case, it is possible to increase not only light extraction efficiency but also color reproducibility of the light-emitting elements.

In the case where a bottom emission display device is manufactured, it is preferable to use, for the pixel electrodes 111, a material (e.g., indium tin oxide or an oxide containing one or more of indium, gallium, zinc, and the like) having transmittance as high as possible in the whole wavelength range of visible light. A surface of each of the pixel electrodes 111 may be provided with a thin metal film (e.g., an alloy of silver and magnesium) that transmits light emitted from the light-emitting layer. The pixel electrodes 111 formed using the material can be referred to as electrodes having a light-transmitting property. In that case, it is possible to increase not only light extraction efficiency but also color reproducibility of the light-emitting elements.

### Formation of Insulating Layer 131

Subsequently, the insulating layer 131 is formed to cover end portions of the pixel electrodes 111 (see FIG. 10(A)). An organic insulating film or an inorganic insulating film can be used for the insulating layer 131. End portions of the insulating layer 131 are preferably tapered to improve step coverage with an EL film to be formed later. In particular, when an organic insulating film is used, a photosensitive material is preferably used so that the shape of the end portions can be easily controlled by the conditions of light exposure and development.

### Formation of EL Film 112Rf

Subsequently, an EL film 112Rf to be the EL layer 112R is formed over the pixel electrodes 111 and the insulating layer 131 (see FIG. 10(B)).

The EL film 112Rf includes at least a film containing a red-light-emitting organic compound. A structure may be employed in which an electron-injection layer, an electron-transport layer, a charge-generation layer, a hole-transport layer, and a hole-injection layer are stacked in addition to the above. The EL film 112Rf can be formed by an evaporation method or a sputtering method, for example. Without limitation to this, any of the above-described film formation methods can be used as appropriate.

### Formation of Resist Mask 143a

Next, a resist mask 143a is formed over the pixel electrode 111 corresponding to the light-emitting element 110R (see FIG. 10(C)). The resist mask 143a can be formed by a lithography step.

### Formation of EL Layer 112R

Then, the EL film 112Rf is etched with the resist mask 143a serving as a mask, so that the EL layer 112R is formed to have an island shape (see FIG. 10(D)). A dry etching method or a wet etching method can be used for the etching step.

### Formation of EL Film 112Gf

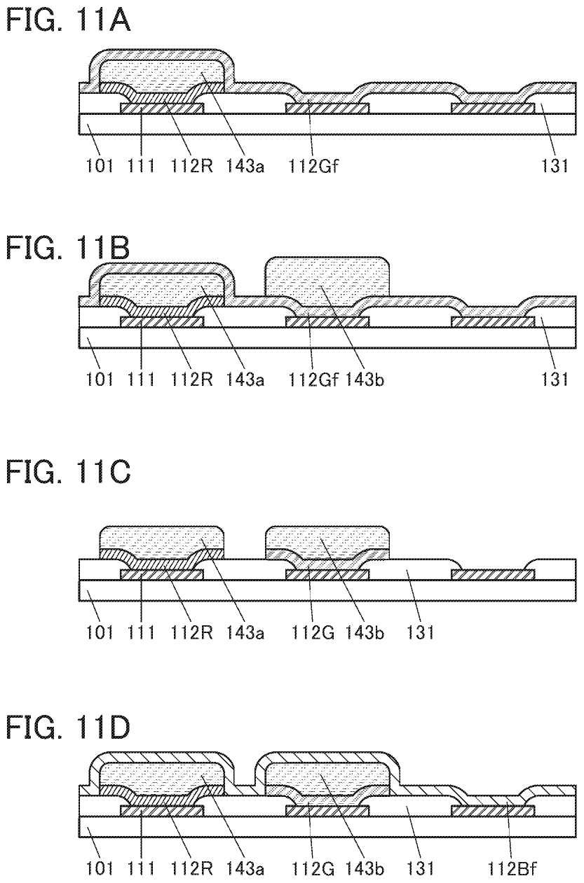

Subsequently, an EL film 112Gf to be the EL layer 112G is formed over the pixel electrodes 111 and the insulating layer 131 that are exposed and the resist mask 143a (see FIG. 11A).

The EL film 112Gf includes at least a film containing a green-light-emitting organic compound. A structure may be employed in which an electron-injection layer, an electron-transport layer, a charge-generation layer, a hole-transport layer, and a hole-injection layer are stacked in addition to the above.

### Formation of Resist Mask 143b

Next, a resist mask 143b is formed over the pixel electrode 111 corresponding to the light-emitting element 110G (see FIG. 11B). The resist mask 143b can be formed by a lithography step.

### Formation of EL Layer 112G

Then, the EL film 112Gf is etched with the resist mask 143b serving as a mask, so that the EL layer 112G is formed to have an island shape (see FIG. 11C). A dry etching method or a wet etching method can be used for the etching step.

### Formation of EL Film 112Bf

Subsequently, an EL film 112Bf to be the EL layer 112B is formed over the pixel electrode 111 and the insulating layer 131 that are exposed, the resist mask 143a, and the resist mask 143b (see FIG. 11D).

The EL film 112Bf includes at least a film containing a blue-light-emitting organic compound. A structure may be employed in which an electron-injection layer, an electron-transport layer, a charge-generation layer, a hole-transport layer, and a hole-injection layer are stacked in addition to the above.

### Formation of Resist Mask 143c

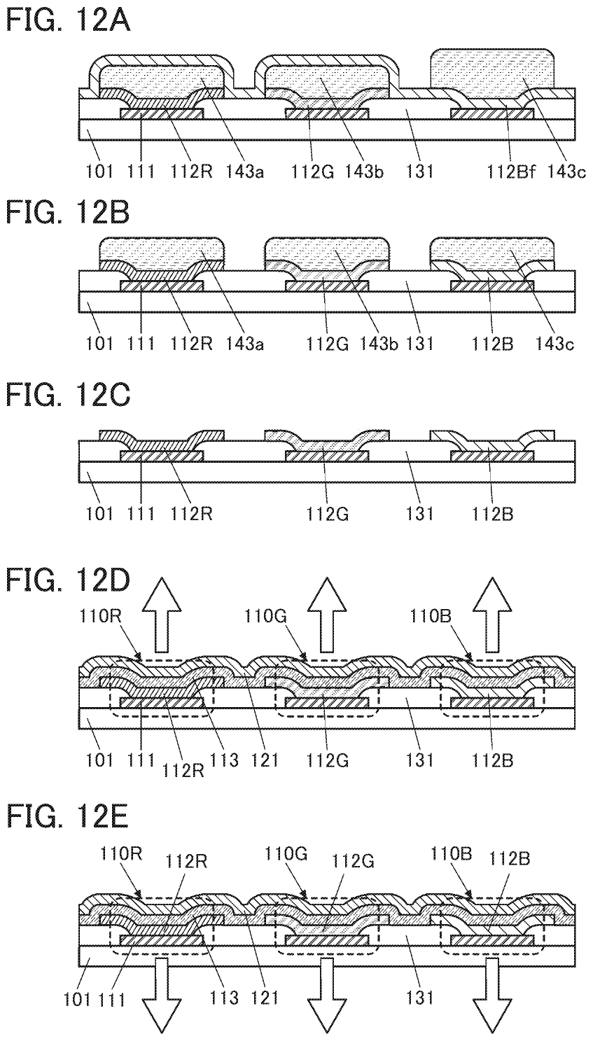

Next, a resist mask 143c is formed over the pixel electrode 111 corresponding to the light-emitting element 110B (see FIG. 12A). The resist mask 143b can be formed by a lithography step.

### Formation of EL Layer 112B

Then, the EL film 112Bf is etched with the resist mask 143c serving as a mask, so that the EL layer 112B is formed to have an island shape (see FIG. 12B). A dry etching method or a wet etching method can be used for the etching step.

### Removal of Resist Mask

Subsequently, the resist mask 143a, the resist mask 143b, and the resist mask 143c are removed (see FIG. 12C). For the removal of the resist masks, a peeling method using an organic solvent can be used, for example. Alternatively, ashing using a dry etching apparatus may be employed, for example.

### Formation of Common Electrode

Then, a conductive film to be the common electrode 113 of the organic EL elements is formed over the EL layer 112R, the EL layer 112G, and the EL layer 112B that are exposed in the previous step and the insulating layer 131. For the step of forming the conductive film to be the common electrode 113, an evaporation apparatus and/or a sputtering apparatus can be used, for example.

In the case where a top emission display device is manufactured, for the common electrode 113, either one of a thin metal film that transmits light emitted from the light-emitting layer (e.g., an alloy of silver and magnesium) and a light-transmitting conductive film (e.g., indium tin oxide or an oxide containing one or more of indium, gallium, zinc, and the like) or a stack of these films can be used. The common electrode 113 formed using such a film can be referred to as an electrode having a light-transmitting property.

When the electrodes having a light-reflecting property are included as the pixel electrodes 111 and the electrode having a light-transmitting property is included as the common electrode 113, light emitted from the light-emitting layers can be emitted to the outside through the common electrode 113. In other words, top emission light-emitting elements are formed.

In the case where a bottom emission display device is manufactured, it is preferable to use, for the common electrode 113, a material (e.g., silver or aluminum) having reflectance as high as possible in the whole wavelength range of visible light. The common electrode 113 formed using the material can be referred to as an electrode having a light-reflecting property.

When the electrodes having a light-transmitting property are included as the pixel electrodes 111 and the electrode having a light-reflecting property is included as the common electrode 113, light emitted from the light-emitting layers can be emitted to the outside through the pixel electrodes 111. In other words, bottom emission light-emitting elements are formed.

### Formation of Protective Layer

Next, the protective layer 121 is formed over the common electrode 113 (see FIG. 12D and FIG. 12E). A sputtering apparatus, a CVD apparatus, an ALD apparatus, or the like can be used for the step of forming the protective layer. FIG. 12D shows a top emission display device and FIG. 12E shows a bottom emission display device.

### Example of Manufacturing Equipment

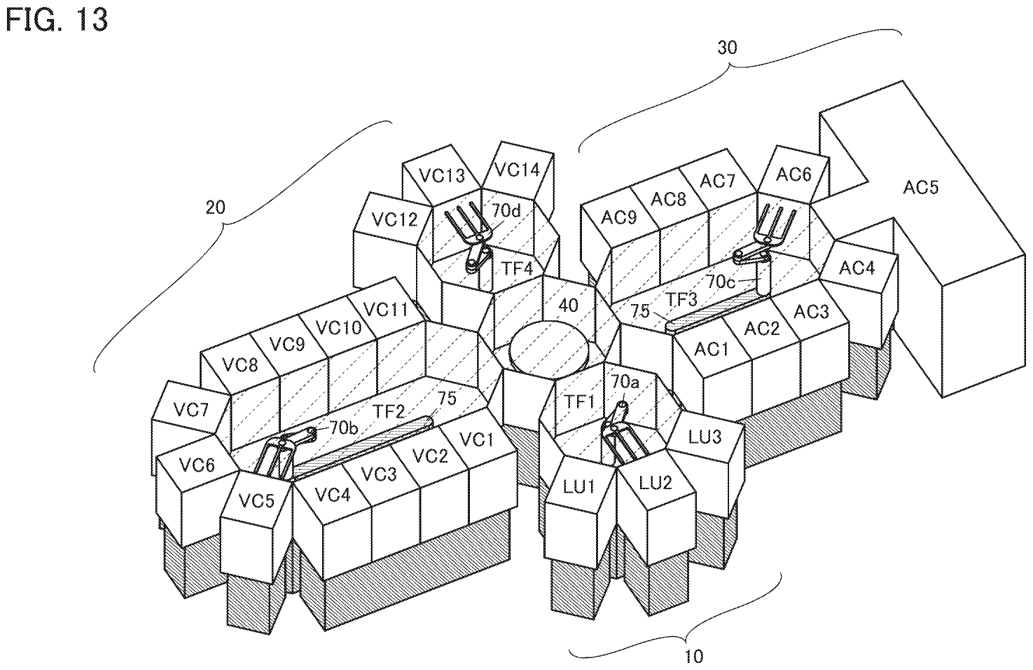

FIG. 13 illustrates an example of manufacturing equipment that can be used for the above-described steps from the formation of the EL film 112Rf up to the formation of the protective layer 121. In FIG. 13 illustrating the example of the manufacturing equipment, whose basic structure is the same as that of the manufacturing equipment in FIG. 1, necessary apparatuses are specifically illustrated in consideration of formation of R, G, and B light-emitting elements, process time shortened by multitasking, and the like.

The vacuum controlled cluster 20 and the atmosphere controlled cluster 30 will be specifically described below. FIG. 13 is a schematic perspective view of the whole of the manufacturing equipment, where utilities, gate valves, and the like are not illustrated. In the drawing, the insides of the transfer chambers TF1, TF2, TF3, and TF4 and the load lock chamber 40 are made visible for clarity.

### Vacuum Controlled Cluster

The vacuum controlled cluster 20 includes a block that includes the transfer chamber TF2 and vacuum process apparatuses VC1 to VC11 and a block that includes the transfer chamber TF4 and vacuum process apparatuses VC12 to VC14. Note that the transfer chamber TF2 and the vacuum process apparatuses VC1 to VC14 may be formed as one block, in which case the vacuum controlled cluster is not divided into two blocks.

The transfer chamber TF2 includes the delivery device 70b. The transfer chamber TF4 includes a delivery device 70d. Here, the delivery device 70b is self-propelled and can move on a rail 75.

### VC1 to VC5

The vacuum process apparatuses VC1 to VC5 are evaporation apparatuses for formation of the EL film 112Rf, the EL film 112Gf, and the EL film 112Bf. For example, the vacuum process apparatuses VC2, VC3, and VC4 can be formation apparatuses for a light-emitting layer (R), a light-emitting layer (G), and a light-emitting layer (B), respectively. The vacuum process apparatuses VC1 and VC5 can be designated as apparatuses for formation of common layers such as an electron-injection layer, an electron-transport layer, a charge-generation layer, a hole-transport layer, and a hole-injection layer.

### VC6 and VC7

The vacuum process apparatus VC6 can be a device detaching the substrate delivering jig described with reference to FIG. 2A and FIG. 2B. The delivery device 70b, with which a substrate alone can be delivered, can carry a substrate into the vacuum process apparatus VC6 and attach the substrate delivering jig to the substrate. In addition, the substrate delivering jig can be detached in the vacuum process apparatus VC6 and the substrate alone can be carried out.

The vacuum process apparatus VC7 can be the substrate reversing device described with reference to FIG. 4A to FIG. 4C. The vacuum process apparatus VC7 can reverse the work substrate 50 as needed.

### VC8 and VC9

The vacuum process apparatuses VC8 and VC9 can be film formation apparatuses for formation of the common electrode 113. For example, the vacuum process apparatus VC8 can be an evaporation apparatus used for formation of a metal film transmitting visible light. The vacuum process apparatus VC9 can be a sputtering apparatus used for formation of a light-transmitting conductive film.

### VC10 and VC11

The vacuum process apparatus VC10 can be a film formation apparatus for formation of the protective layer 121. For example, the vacuum process apparatus VC10 can be a sputtering apparatus. Alternatively, the vacuum process apparatus VC10 may be a CVD apparatus, an ALD apparatus, or the like. Further alternatively, two or more of these film formation apparatuses may be provided as other vacuum process apparatuses VC to form the protective layer 121 as a stacked-layer film.

The vacuum process apparatus VC11 can be a dry etching apparatus for formation of the EL layer 112R, the EL layer 112G, and the EL layer 112B and removal of resist masks. Alternatively, an ashing apparatus may be provided as another vacuum process apparatus VC.

### VC12, VC13, and VC14

One or more of the vacuum process apparatuses VC12, VC13, and VC14 can be a vacuum baking apparatus(es). Since the reliability of an organic EL element is impaired by entry of impurities such as water, it is preferable that vacuum baking (heat treatment under a reduced pressure) be performed in a step preceding formation of the EL film 112Rf, the EL film 112Gf, and the EL film 112Bf to remove impurities such as water attached onto the work substrate 50.

Although the number of each kind of provided apparatus is one in the above-described example, two or three apparatuses with a relatively long process time may be provided. For example, all of the vacuum process apparatuses VC12, VC13, and VC14 can be vacuum baking apparatuses.

### Atmosphere Controlled Cluster

The atmosphere controlled cluster 30 includes the transfer chamber TF3 and the normal-pressure process apparatuses AC1 to AC8.

The transfer chamber TF3 includes the delivery device 70c. The delivery device 70c is self-propelled and can move on the rail 75.

### AC1, AC2, and AC3

As any one or more of the normal-pressure process apparatuses AC1 to AC3, a cleaning apparatus, a wet etching apparatus, a resist peeling apparatus, or the like can be designated. The apparatuses can be selected as appropriate depending on the steps.

### AC4 to AC9

The normal-pressure process apparatuses AC1 to AC9 can be apparatuses used for a lithography step. For example, the normal-pressure process apparatus AC1 can be a resin (photoresist) application apparatus, the normal-pressure process apparatus AC2 can be a light-exposure apparatus, and the normal-pressure process apparatus AC3 can be a development apparatus.

Alternatively, the normal-pressure process apparatus AC1 can be a resin (e.g., UV-curable resin) application apparatus, the normal-pressure process apparatus AC2 can be a nanoimprint apparatus, and the normal-pressure process apparatus AC3 can be a development apparatus. In the case where a development apparatus is not used, a different apparatus may be designated as the normal-pressure process apparatus AC3.

The normal-pressure process apparatuses AC7 to AC9 can be baking apparatuses. In the baking apparatus, pre-baking or post-baking of a photoresist, drying after washing, or the like can be performed.

Table 1 and Table 2 each summarize the steps using the manufacturing equipment illustrated in FIG. 13, the treatment apparatuses, the orientation of the substrate (up: face-up mode, down: face-down mode), and components corresponding to the above-described manufacturing method. Note that the tables omit carrying in and out the substrate to and from the load lock chamber 40 and the apparatuses.

Table 1 shows the steps following the formation of the pixel electrodes 111 up to the formation of one kind of EL layer. These steps are performed for each of the R, G, and B EL layers; accordingly, the steps from No. 1 to No. 16 in Table 1 are performed three times.

TABLE 1

| | | | Orien- | |
|---|---|---|---|---|
| | | | tation of | Correspond- |
| Step | | Treatment | sub- | ing |
| No. | Step | apparatus | strate | component |
| 1 | Washing | AC1 | up | |
| 2 | Vacuum baking | VC12 | up | |
| 3 | Attaching delivery jig | VC6 | up | |
| 4 | Reversing substrate | VC7 | down | |
| 5 | Forming common layer | VC1 | down | EL film |
| 6 | Forming light-emitting | VC2, VC3, | down | 112Rf, 112Gf, |
| | layer | or VC4 | | or 112Bf |
| 7 | Forming common layer | VC5 | down | |
| 8 | Reversing substrate | VC7 | up | |
| 9 | Detaching delivery jig | VC6 | up | |
| 10 | Applying photoresist | AC4 | up | Resist mask |
| 11 | Pre-baking | AC7 | up | 143a, 143b, |
| 12 | Light exposure | AC5 | up | or 143c |
| 13 | Development | AC6 | up | |
| 14 | Post-baking | AC8 | up | |
| 15 | Etching EL film | VC11 | up | EL layer 112R, |
| 16 | Removing resist mask | AC3 | up | 112G, or 112B |

Table 2 shows the steps following the formation of the EL layers 112R, 112G, and 112B up to the formation of the protective layer 121. In replacement of the substrate delivering jig in Step No. 55, the jig 54 attached in Step No. 50 is replaced with the jig 54 having a larger opening portion than the jig 54 attached in Step No. 50. Accordingly, the protective layer covering an end portion of the common electrode can be provided.

TABLE 2

| | | Treat- | Orien- | |
|---|---|---|---|---|
| | | ment | tation of | |
| Step | | appara- | sub- | Corresponding |
| No. | Step | tus | strate | component |
| 49 | Vacuum baking | VC12 | up | |
| 50 | Attaching delivery jig | VC6 | up | |
| 51 | Reversing substrate | VC7 | down | |
| 52 | Forming common electrode | VC8 | down | Common |
| 53 | Forming common electrode | VC9 | down | electrode 113 |
| 54 | Reversing substrate | VC7 | up | |
| 55 | Replacing delivery jig | VC6 | up | |
| 56 | Reversing substrate | VC7 | down | |
| 57 | Forming protective layer | VC10 | down | Protective |
| | | | | layer 121 |
| 58 | Reversing substrate | VC7 | up | |
| 59 | Detaching delivery jig | VC6 | up | |

The manufacturing equipment of one embodiment of the present invention has a function of performing Step No. 1 in Table 1 to Step No. 59 in Table 2 automatically.

This embodiment can be implemented in an appropriate combination with the structures described in the other embodiment.

### REFERENCE NUMERALS

AC: normal-pressure process apparatus, AC1: normal-pressure process apparatus, AC2: normal-pressure process apparatus, AC3: normal-pressure process apparatus, AC5: normal-pressure process apparatus, AC6: normal-pressure process apparatus, AC7: normal-pressure process apparatus, AC8: normal-pressure process apparatus, AC9: normal-pressure process apparatus, LU: load/unload chamber, LU1: load/unload chamber, LU2: load/unload chamber, LU3: load/unload chamber, TF1: transfer chamber, TF2: transfer chamber, TF3: transfer chamber, TF4: transfer chamber, VC: vacuum process apparatus, VC1: vacuum process apparatus, VC2: vacuum process apparatus, VC3: vacuum process apparatus, VC4: vacuum process apparatus, VC5: vacuum process apparatus, VC6: vacuum process apparatus, VC7: vacuum process apparatus, VC8: vacuum process apparatus, VC9: vacuum process apparatus, VC10: vacuum process apparatus, VC11: vacuum process apparatus, VC12: vacuum process apparatus, VC13: vacuum process apparatus, VC14: vacuum process apparatus, 10: load/unload unit, 20: vacuum controlled cluster, 30: atmosphere controlled cluster, 40: load lock chamber, 41: gate valve, 42: gate valve, 43: gate valve, 45: substrate rotating mechanism, 50: work substrate, 51: jig, 52: through hole, 53: through hole, 54: jig, 55: magnet, 56: projection, 57: shape portion, 60: substrate, 70: delivery device, 70a: delivery device, 70b: delivery device, 70c: delivery device, 70d: delivery device, 71: hand portion, 75: rail, 80: substrate reversing device, 81: support, 82: pillar, 83: rotation mechanism, 84: rotation portion, 85a: hand portion, 85b: hand portion, 86a: horizontal movement mechanism, 86b: horizontal movement mechanism, 87: shape portion, 90a: sputtering apparatus, 90b: dry etching apparatus, 91: rail, 92: cathode, 93: anode, 95: cathode, 96: anode, 100: display device, 101: substrate, 110B: light-emitting element, 110G: light-emitting element, 110R: light-emitting element, 111: pixel electrode, 112B: EL layer, 112Bf: EL film, 112G: EL layer, 112Gf: EL film, 112R: EL layer, 112Rf: EL film, 112W: EL layer, 113: common electrode, 121: protective layer, 131: insulating layer, 143a: resist mask, 143b: resist mask, 143c: resist mask

1. Manufacturing equipment of a light-emitting device, the manufacturing equipment comprising a load lock chamber, a vacuum controlled cluster, and an atmosphere controlled cluster,
wherein the load lock chamber is connected to the vacuum controlled cluster through a first gate valve,
wherein the load lock chamber is connected to the atmosphere controlled cluster through a second gate valve,
wherein a pressure in the load lock chamber is controlled to be a reduced pressure or an atmosphere in the load lock chamber is controlled to be an inert gas atmosphere,
wherein a pressure in the vacuum controlled cluster is controlled to be a reduced pressure,
wherein an atmosphere in the atmosphere controlled cluster is controlled to be an inert gas atmosphere,
wherein the vacuum controlled cluster comprises a first delivery device, a plurality of film formation apparatuses, and an etching apparatus,
wherein the atmosphere controlled cluster comprises a second delivery device and a plurality of apparatuses performing a lithography step, and
wherein the manufacturing equipment forms the light-emitting device by forming, over a substrate provided with a first electrode, an island-shaped organic compound layer over the first electrode, a second electrode over the organic compound layer, and a protective film over the second electrode through a plurality of film formation steps in the vacuum controlled cluster, a lithography step in the atmosphere controlled cluster, and an etching step in the vacuum controlled cluster.

2. The manufacturing equipment of the light-emitting device, according to claim 1,
wherein each of the plurality of film formation apparatuses is one or more selected from an evaporation apparatus, a sputtering apparatus, a CVD apparatus, and an ALD apparatus, and
wherein the etching apparatus is a dry etching apparatus.

3. The manufacturing equipment of the light-emitting device, according to claim 1,
wherein the vacuum controlled cluster comprises a vacuum baking apparatus.

4. The manufacturing equipment of the light-emitting device, according to claim 1,
wherein the load lock chamber is connected to a vacuum baking apparatus through a third gate valve.

5. The manufacturing equipment of the light-emitting device, according to claim 1,
wherein the plurality of apparatuses performing the lithography step comprise an application apparatus, a light-exposure apparatus, a development apparatus, and a baking apparatus.

6. The manufacturing equipment of the light-emitting device, according to claim 1,
wherein the plurality of apparatuses performing the lithography step comprise an application apparatus and a nanoimprint apparatus.

7. The manufacturing equipment of the light-emitting device, according to claim 1,
wherein the load lock chamber comprises a substrate rotating mechanism rotating the substrate about an axis perpendicular to a center of a top surface of the substrate.

8. The manufacturing equipment of the light-emitting device, according to claim 1,
wherein the load lock chamber is connected to either a load/unload chamber or a load chamber and an unload chamber through a fourth gate valve.

9. The manufacturing equipment of the light-emitting device, according to claim 1,
wherein in the vacuum controlled cluster, the substrate attached to a substrate delivering jig is subjected to treatment.

10. The manufacturing equipment of the light-emitting device, according to claim 9,
wherein the substrate delivering jig comprises a first jig and a second jig, and
wherein the substrate is held between the first jig and the second jig.

11. The manufacturing equipment of the light-emitting device, according to claim 10,
wherein the first jig comprises a flat-plate portion having a rectangular top surface shape, and
wherein the first jig comprises a plurality of through holes penetrating the first jig from a first side surface of the flat-plate portion to a second side surface opposing the first side surface.

12. The manufacturing equipment of the light-emitting device, according to claim 11,
wherein the through holes are used to deliver the substrate to which the substrate delivering jig is attached and to reverse the substrate.

13. The manufacturing equipment of the light-emitting device, according to claim 10,
wherein the second jig comprises an opening portion.

14. The manufacturing equipment of the light-emitting device, according to claim 9,
wherein the vacuum controlled cluster comprises a device detaching the substrate delivering jig.

15. The manufacturing equipment of the light-emitting device, according to claim 9,
wherein the vacuum controlled cluster comprises a device reversing the substrate to which the substrate delivering jig is attached.
